(19) United States
(12) Patent Application Publication
(10) Pub. No.: US 2013/0299844 A1
(43) Pub. Date: Nov. 14, 2013

(54) ENHANCED LIGHT EXTRACTION EFFICIENCY FOR LIGHT EMITTING DIODES

(71) Applicant: CASE WESTERN RESERVE UNIVERSITY, Cleveland, OH (US)

(72) Inventor: Hongping ZHAO, Cleveland Heights, OH (US)

(21) Appl. No.: 13/843,207

(22) Filed: Mar. 15, 2013

Related U.S. Application Data
(60) Provisional application No. 61/643,997, filed on May 8, 2012.

(51) Int. Cl. H01L 33/58; H01L 33/32

(52) U.S. Cl. CPC H01L 33/58; H01L 33/32
USPC 257/76; 438/29; 257/95

(57) ABSTRACT

Systems, methods, and other embodiments associated with increased light extraction efficiency in light emitting diodes are described. According to one embodiment, a light emitting diode apparatus includes a device having a first material and a second material separated by an active region. The apparatus further includes a plurality of curvatures formed on the second semiconductor material. The curvatures may be hemi-sphereical, hemi-ellipsoidic, micro domes, or micro domes with a flat surface. The plurality of curvatures and the second material have the same index of refraction.

### CROSS REFERENCE TO RELATED APPLICATIONS

This patent disclosure claims the benefit of U.S. provisional application serial No. 61/643,997 filed on May 8, 2012, which is hereby wholly incorporated by reference.

### BACKGROUND

The background description provided herein is for the purpose of generally presenting the context of the disclosure. Work of the presently named inventor(s), to the extent the work is described in this background section, as well as aspects of the description that may not otherwise qualify as prior art at the time of filing, are neither expressly nor impliedly admitted as prior art against the present disclosure.

A light-emitting diode (LED) is a semiconductor light source. When a forward voltage is applied to an LED, electrons and holes are able to recombine within the device, releasing energy in the form of photons (i.e., light). One challenge to producing high external quantum efficiency LEDs is the difficulty in extracting the photons from the LEDs into the ambient media, referred to as low light extraction efficiency. Photons are subject to total internal reflection at the interface between the semiconductors, with a high refractive index, and the ambient media, having a lower refractive index. Furthermore, the transverse magnetic (TM) component of the spontaneous emission from the active region of the semiconductor dominates the transverse electric (TE) component for shorter wavelength (e.g., deep ultraviolet wavelength region) AlGaN based LEDs. TM polarization is oriented along the direction normal to the semiconductor surface, leading to extremely low light extraction efficiency.

The III-nitride based LEDs cover a wide spectral range from deep-ultraviolet, ultraviolet, visible to near infrared wavelengths. Quantum wells (QWs) are used to confine the carriers (electrons and holes) for efficient carrier recombination to generate photons. For a QW based LED, the wavelength of the light emitted depends on both the QW thickness and the band gap of the compound material forming the active region where electrons and holes recombine and generate photons. Conventionally, LEDs have planar surfaces that exacerbate total internal reflection.

### BRIEF DESCRIPTION OF THE DRAWINGS

The accompanying drawings, which are incorporated in and constitute a part of the specification, illustrate various systems, methods, and other embodiments of the disclosure. Illustrated element boundaries (e.g., boxes, groups of boxes, or other shapes) in the figures represent one example of the boundaries. In some examples one element may be designed as multiple elements or multiple elements may be designed as one element. In some examples, an element shown as an internal component of another element may be implemented as an external component and vice versa.

FIG. 1A illustrates an example of a prior art approach to enhance light extraction in LEDs.

FIG. 1B illustrates an example of a prior art approach to enhance light extraction in LEDs.

FIG. 1C illustrates an example of a prior art approach to enhance light extraction in LEDs.

FIG. 2 illustrates one embodiment of a method for fabricating an LED with enhanced light extraction efficiency.

FIG. 3A illustrates an embodiment of a device associated with enhanced light extraction efficiency for an LED.

FIG. 3B illustrates an embodiment of a monolayer of microspheres on a device associated with enhanced light extraction efficiency for an LED.

FIG. 3C illustrates an embodiment of a plurality of curvatures on a device associated with enhanced light extraction efficiency for an LED.

FIG. 4 illustrates one embodiment of a device associated with enhanced light extraction efficiency for an LED.

FIG. 5 illustrates example spontaneous emission data with transverse magnetic (TM) and transverse electric (TE) components.

FIG. 6 illustrates example light extraction efficiency enhancement data of LEDs with curvatures as a function of the curvature diameter.

FIG. 7 illustrates example total light extraction efficiency enhancement data as a function of p-type layer thickness for LEDs with curvatures as compared to that of the conventional LEDs with flat surface.

FIG. 8A illustrates example diameter (D) for the plurality of curvatures on a device associated with enhanced light extraction efficiency for an LED.

FIG. 8B illustrates example diameter (D) and height (h) for the plurality of curvatures on a device associated with enhanced light extraction efficiency for an LED.

FIG. 9 illustrates example data for the far field TM polarized emission pattern associated with enhanced light extraction efficiency for an LED.

FIG. 10 illustrates one embodiment of a device associated with enhanced light extraction efficiency for an LED.

FIG. 11 illustrates example spontaneous emission spectra (Rₛₚ) data with TE and TM components.

FIG. 12 illustrates p-type layer thickness dependence of light extraction efficiency for thin-film-flip-chip (TFFC) LEDs.

### DETAILED DESCRIPTION

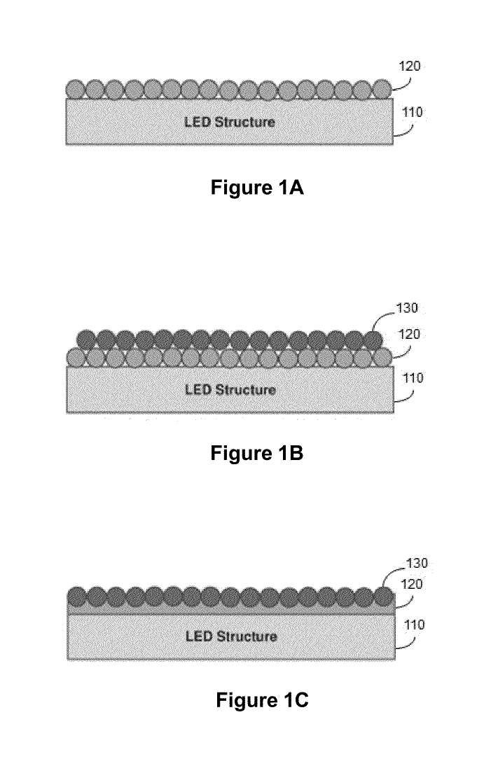

To mitigate low light extraction efficiency in LEDs (e.g., visible LEDs, deep-UV/UV LEDs, top-emitting LEDs, thin-film-flip-chip LEDs, organic LEDs), previous approaches have included the addition of silicon dioxide (SiO₂) and polystyrene microspheres as illustrated in FIG. 1. Conventionally, LEDs have a generally planar LED structure 110. For example, the LED structure 110 may have a p-type surface which exacerbates total internal reflection. Typically, a closely packed monolayer of polystyrene microspheres 120 is formed on the LED structure 110 as shown in FIG. 1A. The monolayer of polystyrene microspheres 120 is laid using rapid convection deposition method. Next a closely packed monolayer of SiO₂ microspheres 130 is formed on top of the monolayer of polystyrene microspheres 120 as shown in FIG. 1B. The monolayer of polystyrene microspheres 120 acts as an adhesive for the monolayer of SiO₂ microspheres 130. Shown in FIG. 1C, a heat treatment is applied to covert the polystyrene microspheres 120 to a planar layer. The SiO₂ microspheres 130 sink into the polystyrene monolayer 120 as spheres.

The polystyrene is subject to material degradation over time and degradation due to heat exposure. In addition, polystyrene has strong absorption for the UV light, which limits its application in deep-UV/UV LEDs. Furthermore, the monolayer of SiO₂ microspheres and polystyrene have lower index of refraction (IOR) than the IOR of the LED structure. Photons attempting to exit the LED structure still experience total internal reflection due to the juxtaposition of differing indexes of refraction at the interface between LEDs and polystyrene. Total internal reflection is an optical phenomenon that happens when a ray of light strikes a boundary at an angle larger than a particular critical angle with respect to the normal of the surface. The critical angle is determined by the ratio of the refractive indexes. Thus, the approach based on SiO₂/polystyrene microspheres has limited enhancement of light extraction efficiency, associated with potential material or device degradations.

Systems and methods are described herein that are associated with increasing light extraction efficiency for LEDs by forming a plurality of curvatures (e.g., hemispherical, hemi-ellipsoidic, microdomes, microdomes with flat surface) at the surface of the LED structures. The curvatures increase the light escape cone allowing more photons to escape thereby increasing light extraction efficiency of LEDs. In one embodiment, the surface of the LED structure is a p-type material. To create the curvatures, a layer of self-assembled microspheres is deposited on the p-type material. The self-assembled microspheres and p-type layer are etched. Reactive ion etching (RIE) conditions can be tuned to etch both the self-assembled microspheres and the p-type layer simultaneously. Therefore, the p-type layer can be patterned with desired curvatures. The curvatures on the p-type layer increase the light escape cone thereby reducing total internal reflections that reduce the amount of light able to be extracted from the LED.

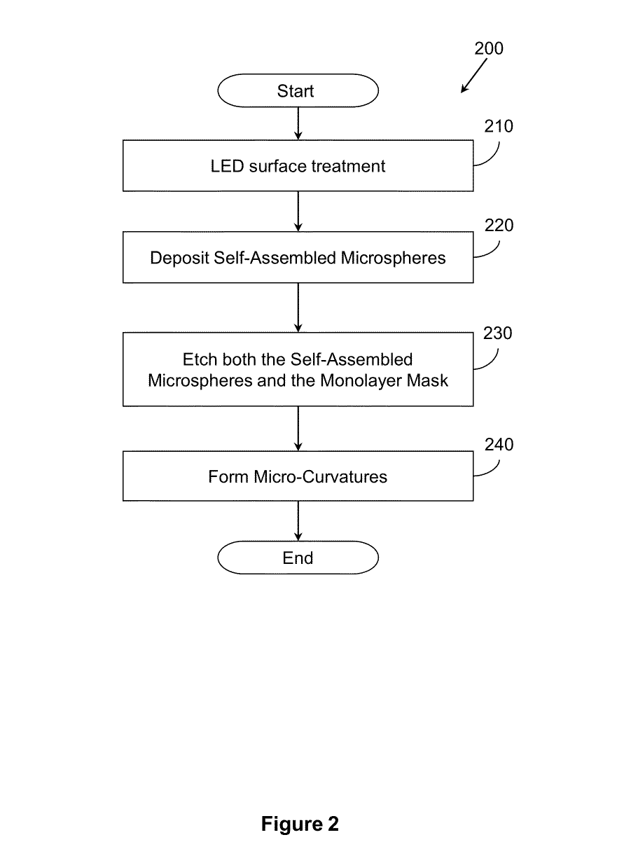

FIG. 2 illustrates one embodiment of a method for fabricating an LED with increased light extraction efficiency. The surface of the LED is initially hydrophobic. At 210 a surface treatment is performed for the surface of the LED to convert the hydrophobic property of the surface to a hydrophilic property. Converting the surface of the LED to be hydrophilic facilitates deposition of microspheres on the surface of the LED. UV ozone could be used for the surface treatment.

At 220, a layer of self-assembled microspheres is deposited on the p-type material. The self-assembled microspheres are a close-packed monolayer of dielectric microspheres. The monolayer of dielectric microspheres are deposited using a self-assembled approach (e.g., rapid convective deposition, dip coating, spincoating). At 230, the self-assembled microspheres and p-type layer are etched. Reactive ion etching (RIE) conditions can be tuned to etch both the self-assembled microspheres and p-type layer simultaneously. The self-assembled microspheres and p-type layer are etched to form, at 240, a plurality of curvatures (e.g., hemispherical, hemi-ellipsoidic, microdome, or microdomes with flat surface) on the p-type layer. During etching, the monolayer of dielectric microspheres is removed. The curvatures are formed from the p-type material. The curvatures increase the light escape cone allowing more photons to escape the p-type layer thereby increasing light extraction efficiency of LEDs.

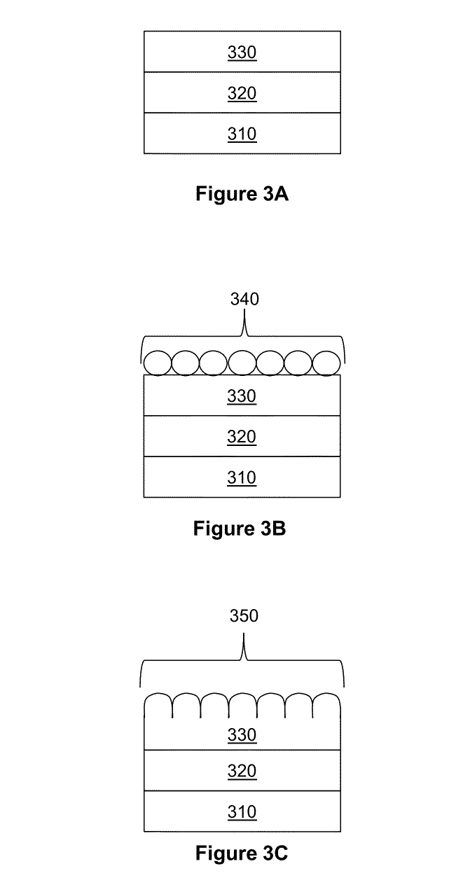

FIG. 3A illustrates one embodiment of a device of an LED. The device includes a first material 310, an active region 320, and a second material 330. The first material and the second material may be semiconductor materials created by doping (e.g., ion implantation, diffusion, or epitaxy). In one embodiment, the first material 310 is an n-type material and the second material 330 is a p-type material. One of ordinary skill in the art will recognize any number of combinations of specific p-type and n-type materials may be used.

FIG. 3B illustrates one embodiment of a monolayer of microspheres 340 on the device. FIG. 3C illustrates one embodiment of curvatures 350 on the second material 330 of the device. The size and shape of the curvatures 350 may be tailored to the LED. For example, the size of III-nitride curvatures is in the range of submicron to micron. With relative thick top surface of the second material 330, it is more flexible to tune the size of the III-nitride curvatures. The light extraction efficiency is obtained by taking the ratio of the extracted light power on the detection plane and the dipole source power.

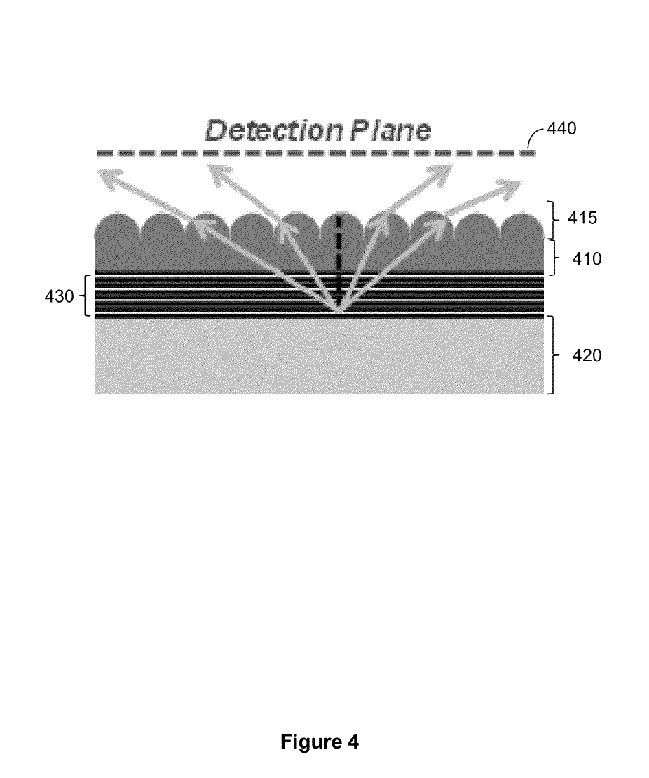

FIG. 4 illustrates one embodiment of an ultra-violet (UV) LED with increased light extraction efficiency. In one embodiment, the UV LEDs are based on wide band gap aluminum gallium nitride (AlGaN) quantum wells (QWs) with aluminum nitride (AlN) barriers as active region. AlGaN curvatures 415 are formed from the p-AlGaN layer 410. The layer under the AlGaN/AlN QWs is an n-AlN layer 420. The AlGaN curvatures 415 are formed from the self-assembled microspheres and the p-AlGaN layer by RIE etching of both the microspheres and the p-AlGaN layer with an appropriate etching rates ratio. The etching rates ratio of the microspheres and p-type material will determine the shape and aspect ratio of the AlGaN curvatures 415. The etching rate ratio is controlled by tuning the RIE conditions (e.g., etching gas component, flow rate, RF power, working pressure).

AlGaN QWs LEDs with AlGaN curvatures 415 on the top surface of the p-AlGaN 410 allow more photons from an active region 430 to reach the detection plane 440. The AlGaN curvatures 415 are formed as part of the p-AlGaN layer 410. The equivalent index of refraction of the AlGaN curvature 415 and the p-AlGaN layer 410 as well as the arc of the AlGaN curvatures 415 increase the light escape cone thereby reducing total internal reflections. Reducing the total internal reflection increases the amount of light extracted from the LED.

While the embodiment of FIG. 4 includes p-AlGaN layer 410 that is constructed of AlGaN, the p-AlGaN layer 410 may be constructed of a different material. For example, p-AlGaN layer 410 may be constructed of p-AlN instead. Accordingly, the AlGaN curvatures 415 constructed of AlGaN would then be constructed of p-AlN as well.

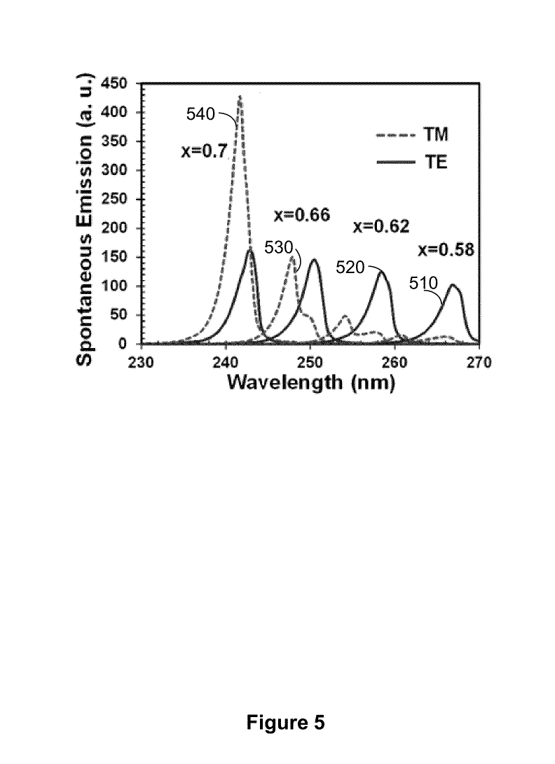

FIG. 5 illustrates example spontaneous emission spectra (Rₛₚ) data for 3-nm AlₓGa₁₋ₓN QWs with AlN barriers, for x=0.58, x=0.62, x=0.66 and x=0.7, respectively. In AlGaN QWs based UV LEDs, the heavy hole (HH), light hole (LH) and crystal-field split-off hole (CH) energy bands in the valence band cross over between HH/LH and CH bands. Example data is shown for AlₓGa₁₋ₓN quantum wells (QWs) with different aluminum content. For low aluminum content AlₓGa₁₋ₓN quantum wells, with x<0.66, the dominant transition is between the conduction and HH/LH bands, that is the transverse electric (TE) polarized spontaneous emission component. For example, peaks 510 and 520 illustrate peaks in the TE component that dwarf the TM component for the same x values.

As the aluminum content increases, the TM polarized component becomes the dominant component of the total Rₛₚ. Accordingly, for high Al-content AlₓGa₁₋ₓN QWs, with x>0.66, the dominant transition between the conduction band and CH band is the transverse magnetic (TM) polarized spontaneous emission component. Peaks 530 and 540 illustrate that the TM component dwarfs the TE component for the same x values. Thus, with a higher Al content, light extraction efficiency is focused on the TM polarized spontaneous emission component. The TM component has extremely low light extraction efficiency. Accordingly, it is helpful to enhance the light extraction efficiency of the TM spontaneous emission component for AlGaN QWs LEDs with high Al-content.

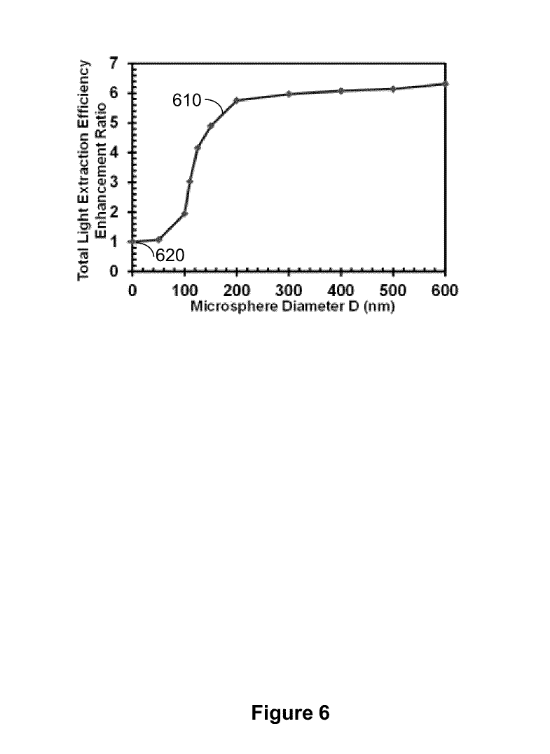

FIG. 6 illustrates example light extraction efficiency enhancement data for AlGaN QW LEDs with AlGaN curvatures as a function of the curvature diameter. The AlGaN micro-curvature size affects the light extraction efficiency for the TM polarized spontaneous emission component. The curve 610 illustrates the ratio of the light extraction efficiency enhancement of the AlGaN QW LEDs (ₚₑₐₖ=250 nm, full width half maximum=10 nm) with AlGaN curvatures as compared to that of the conventional AlGaN QW LEDs with flat surface as a function of the curvature diameter (D).

In one embodiment, the top p-AlGaN layer thickness is a constant of 300 nm. At point 620, the diameter is zero which represents the case for the conventional LEDs with flat surface. The point 620 is normalized to 1. As the curvatures diameters D increase, the light extraction efficiency enhancement ratio increases. The enhancement ratio increases significantly from 1 (D=0) to 5.7 (D=200 nm). As the curvatures' diameter D increases from D=200 nm to D=600 nm, the enhancement ratio increases slightly. A relatively small diameter of the AlGaN curvatures (D<200 nm) may be formed due to the limited thickness of the top p-AlGaN layer (˜200-300 nm) and the potential effect of the curvatures fabrication on the AlGaN QWs active region if the diameter of the dielectric self-assembled microspheres is close to the p-AlGaN layer thickness. Accordingly, the AlGaN micro-curvature size affects the light extraction efficiency significantly for the TM polarized spontaneous emission component.

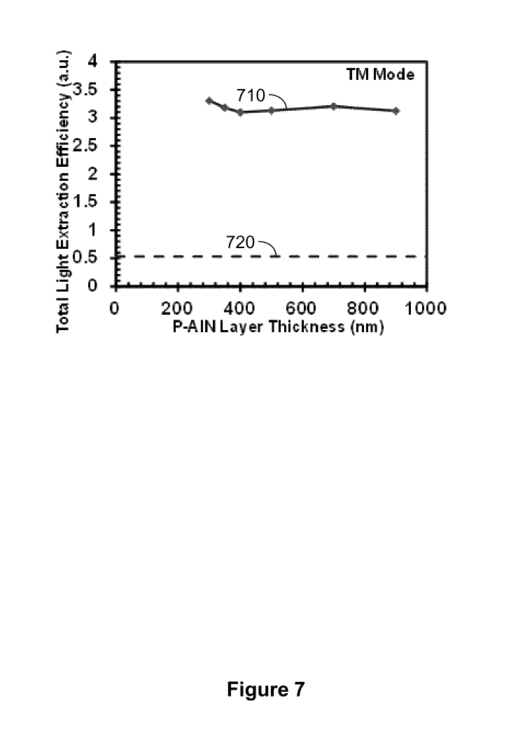

FIG. 7 illustrates example total light extraction efficiency data as a function p-AlN layer thickness for both LEDs with curvatures and conventional LEDs with flat surface. Specifically, one example of the total light extraction efficiency as a function of p-AlN layer thickness is shown. Curve 710 illustrates total light extraction efficiency for LEDs with curvatures (e.g., micro-hemispheres, micro-hemiellipsoid). Curve 720 illustrates total light extraction efficiency for conventional LEDs without curvatures. Therefore, given equal thickness, LEDs with curvatures (e.g., micro-hemispheres with 500 nm diameter) have greater total light extraction efficiency as compared to conventional LEDs. The p-AlN layer thickness affects the light extraction efficiency enhancement ratio slightly.

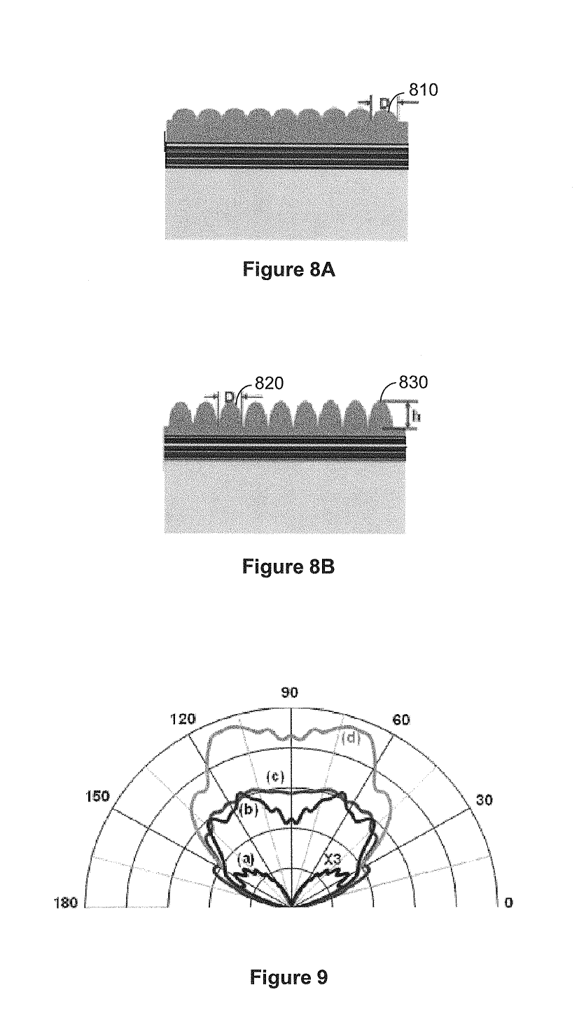

FIG. 8A illustrates diameter (D) for the curvatures where the curvatures are hemispheres. D at 810 illustrates the diameter of a hemisphere. For the hemisphere, the height is equal to half the diameter. FIG. 8B illustrates diameter (D) and height (h) for the curvatures where the curvatures are hemi-ellipsoids. D at 820 is the diameter of a hemi-ellipsoid. The height of a hemi-ellipsoid is variable; h, at 830, is the height of the hemi-ellipsoid.

FIG. 9 plots example data for the far field TM polarized emission pattern (with 90 degrees as the normal to the LED emission surface) for AlGaN QWs deep UV LEDs with flat surface and with curvatures. For example, curve (a) represents far field TM polarized emission pattern data for a flat surface without curvatures (the amplitude has been multiplied by 3 times). Curve (b) represents far field TM polarized emission pattern data for micro-hemispheres that have diameters of 200 nm and p-type material thickness of 300 nm. Curve (c) represents far field TM polarized emission pattern data for micro-hemispheres that have diameters of 500 nm and p-type material thickness of 300 nm. Curve (d) represents far field TM polarized emission pattern data for micro-domes that have diameters of 200 nm, p-type material thickness of 300 nm, and heights of 175 nm.

The enhancement factor ranges between 5.8-6.2 times for the deep UV LEDs with AlGaN curvatures (D=500 nm) as compared to that of the conventional LEDs with flat surface. The LEDs with p-AlGaN layer thickness of 300 nm shows the enhancement of 6.2 times. Accordingly, LEDs with hemiellipsoids show the increased light extraction efficiency enhancement. Likewise, for hemispheres, such as in curve (c) have an increased light extraction enhancement by a factor of 5.8-6.2 as compared to the flat surface represented by curve (a). In another embodiment, an III-nitride micro-dome with a diameter of 200 nm and a height of 175 nm, has an enhancement factor of 7.3 times that of a conventional LED with a generally planar surface.

The far field emission pattern indicates that the LED structure with AlGaN curvatures increases light extraction efficiency of the TM emission component for a wide range of angles, especially in the directions normal to the LED device surface. The increase in far field radiance of the deep UV LEDs with AlGaN curvatures can be attributed to the enhanced scattering of photons and enlargement of the photon escape cone from the hemispherical or hemiellipsoidic shaped curvatures.

The systems and methods described herein can be implemented on Thin-Film-Flip-Chip (TFFC) Light-Emitting Diodes (LEDs). In one embodiment, flip-chip LEDs are achieved by submounting the p-gallium nitride (GaN) on a high reflectance-metallic mirror to form the vertical LED configuration, which allows the photons to emit from the substrate side. The TFFC design is achieved by removing the substrate (e.g. by laser lift-off), which allows more flexible surface texturing and patterning process on the exposed n-GaN layer to enhance the light extraction efficiency.

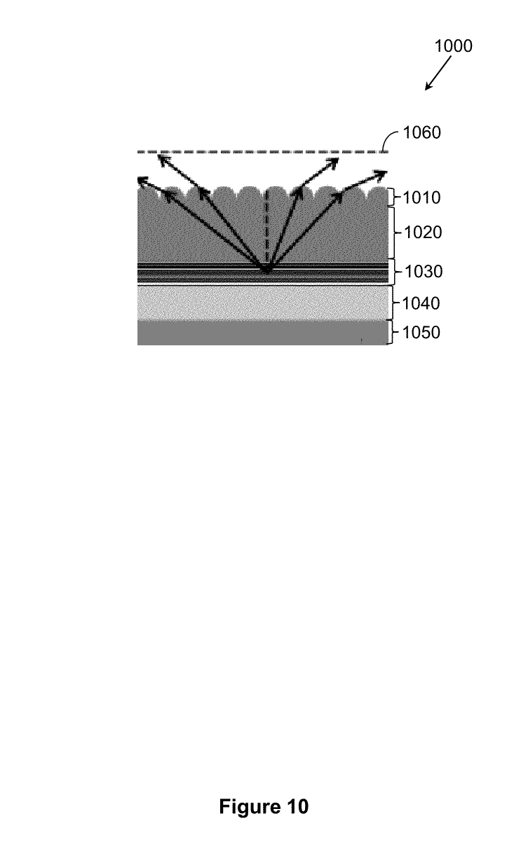

FIG. 10 illustrates one embodiment of GaN curvatures formed on an n-GaN layer for further enhancing the LED light extraction efficiency. The device 1000 includes curvatures 1010, the n-GaN layer 1020, an active region 1030, a p-GaN layer 1040, and a bottom mirror 1050.

The curvatures 1010 are formed by reactive ion etching (RIE) of the n-GaN layer 1020 with a self-assembled microspheres monolayer applied as a mask. The spherical shape of the mask could be transferred to the n-GaN layer 1020 when the etching rates for both n-GaN layer 1020 and microspheres are appropriate by tuning the RIE etching conditions.

The close-packed monolayer of dielectric microspheres is deposited on n-GaN layer 1020 using self-assembled approaches, such as rapid convective deposition, dip coating and spin coating. The close-packed monolayer of dielectric microspheres and the underneath n-GaN layer 1020 are etched simultaneously to form the curvatures 1010 on the n-GaN layer 1020 that allows larger amount of light to be extracted outside the device and onto the detection plane 1060.

The light originates from the active region 1030, and part of the light will be reflected from the bottom mirror 1050. Accordingly, the thickness of p-GaN layer 1040 has critical impact on the light extraction efficiency due to the interference between the wave emitted directly from the dipole source and the reflected waves from the bottom mirror 1050.

Note that in the TFFC LEDs, the QWs active region is placed relatively close to the reflective metallic bottom mirror 1050 (on the order of 150-400 nm). The light emitted directly from QWs will interfere with the reflected waves from the bottom mirror, and the coupled interference patterns in the escape cone will lead to changes in the light extraction efficiency from conventional TFFC LEDs. The LED light extraction efficiency is calculated using three-dimensional finite difference time domain (FDTD) method. In the FDTD calculations for conventional TFFC InGaN QWs LEDs with flat surface, the distance between indium gallium nitride (InGaN) QWs active region and reflective layer could be modified by varying the p-GaN layer thickness, which affects the LED light extraction efficiency.

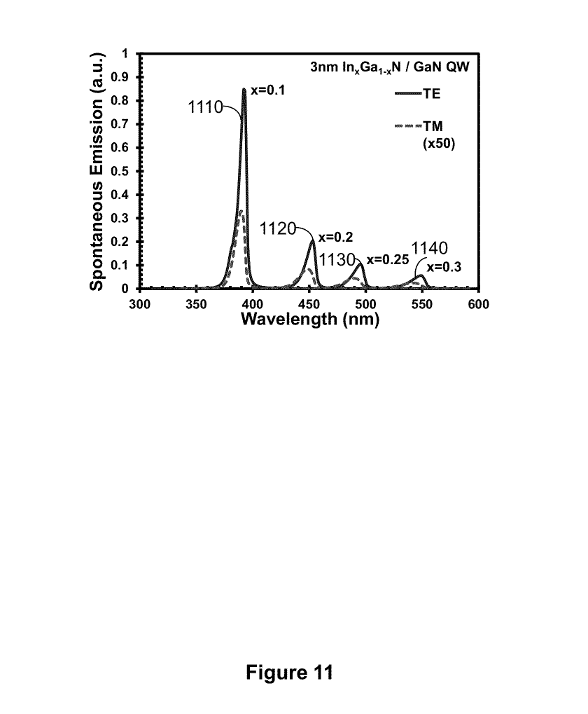

FIG. 11 illustrates example spontaneous emission spectra (Rₛₚ) data for InₓGa₁₋ₓN QWs LEDs with x=0.1, x=0.2, x=0.25 and x=0.3, respectively. The TM component is shown multiplied by a factor of 50. In this example, the TE spontaneous emission component dominates the total Rₛₚ in the visible wavelength regime. Specifically, peaks 1110, 1120, 1130, and 1140 are larger than their respective TM counterparts.

The light extraction efficiency of the TE polarized spontaneous emission component for the conventional TFFC InGaN QWs LEDs with various p-GaN layer thickness was calculated at wavelength peak=460 nm. In one embodiment, p-GaN thickness of 195 nm was obtained to increase light extraction of the conventional InGaN QWs TFFC LEDs with a flat surface.

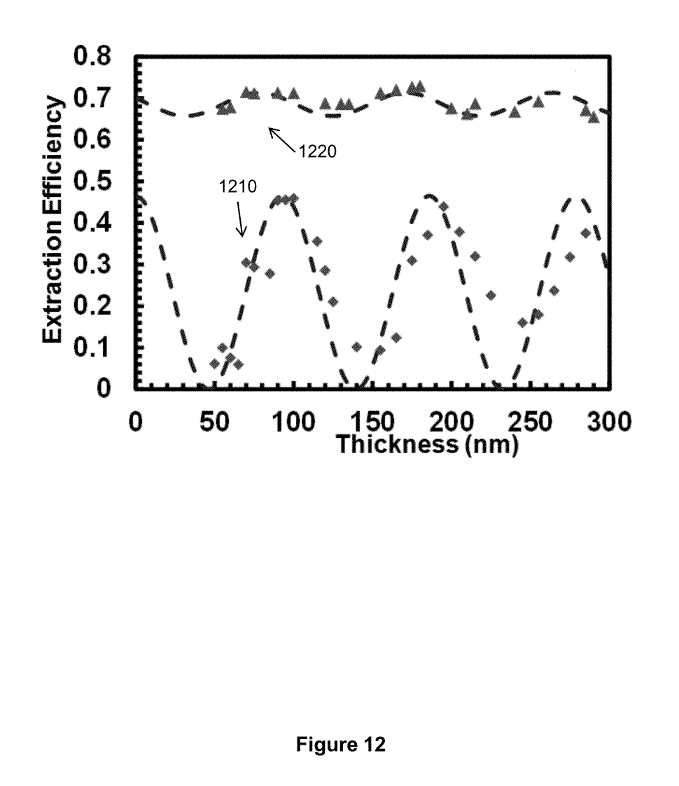

FIG. 12 illustrates layer thickness dependence of light extraction efficiency. The thickness of the bottom layer (as shown by p-GaN layer 1040 in FIG. 10) affects the light extraction efficiency due to the interference of emitted waves and reflected waves. The affect of the layer thickness is drastic for conventional LEDs with flat surfaces as illustrated by curve 1210. The light extraction efficiency for conventional LEDs with flat surfaces as illustrated by curve 1210 is periodic in nature and has a large amplitude.

The light extraction efficiency for the LEDs with curvatures, illustrated by curve 1220, is also periodic nature but with smaller amplitude as compared to conventional LEDs with flat surfaces as illustrated by curve 1210. The curvatures result in a larger light escape cone which leads to light extraction efficiency enhancement. Therefore, with curvatures the light extraction efficiency is less dependent on the layer thickness.

Systems, methods, and other embodiments associated with increased light extraction efficiency in light emitting diodes are described herein. Curvatures are formed by etching both a self-assembled microspheres and the top n-type layer in a single operation. Therefore, the curvatures have the same index of refraction as the n-type layer. The equivalent index of refraction and the arc of the curvatures increase the light escape cone thereby reducing total internal reflections that reduce the amount of light able to be extracted from the LED.

The following includes definitions of selected terms employed herein. The definitions include various examples and/or forms of components that fall within the scope of a term and that may be used for implementation. The examples are not intended to be limiting. Both singular and plural forms of terms may be within the definitions.

References to “one embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in one embodiment” does not necessarily refer to the same embodiment, though it may.

While for purposes of simplicity of explanation, illustrated methodologies are shown and described as a series of blocks. The methodologies are not limited by the order of the blocks as some blocks can occur in different orders and/or concurrently with other blocks from that shown and described. Moreover, less than all the illustrated blocks may be used to implement an example methodology. Blocks may be combined or separated into multiple components. Furthermore, additional and/or alternative methodologies can employ additional, not illustrated blocks.

To the extent that the term “includes” or “including” is employed in the detailed description or the claims, it is intended to be inclusive in a manner similar to the term “comprising” as that term is interpreted when employed as a transitional word in a claim.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the disclosure is not limited to the specific details, the representative apparatus, and illustrative examples shown and described. Thus, this application is intended to embrace alterations, modifications, and variations that fall within the scope of the appended claims.

What is claimed is:

1. A light emitting diode apparatus, comprising:
a device having a first material and a second material separated by an active region; and
a plurality of curvatures formed on the second material, where the plurality of curvatures and the second material have the same index of refraction.

2. The light emitting diode apparatus of claim 1, where the plurality of curvatures are one of hemi-spherical, hemi-ellipsoidic, microdomes, or microdomes with a flat surface.

3. The light emitting diode apparatus of claim 1, where the plurality of curvatures are formed from the second material.

4. The light emitting diode apparatus of claim 1, where the active region is constructed of aluminum gallium nitride (AlGaN).

5. The light emitting diode apparatus of claim 4, where an aluminum content of the active region determines whether a transverse magnetic component or a transverse electric component is dominant in a spontaneous emission spectra of the device.

6. The light emitting diode apparatus of claim 1, where the first semiconductor material is an n-type material and the second semiconductor material is a p-type material.

7. A method, comprising:
depositing a layer of microspheres as the monolayer mask on a surface of a light emitting diode (LED); and
etching the monolayer mask and the surface of the LED to form a plurality of curvatures on the surface of the LED.

8. The method of claim 7, where the etching is tuned to etch both the monolayer mask and the surface of the LED in a single operation.

9. The method of claim 7, where the etching comprises using reactive ion etching.

10. The method of claim 7, where the surface of the LED is hydrophobic, performing a surface treatment to the surface of the LED to make the surface of the LED hydrophilic.

11. The method of claim 7, where shapes of the plurality of curvatures are based, at least in part, on shapes of the microspheres, and where the shape of a curvature is controlled through the etching to increase a light escape cone allowing an increased number of photons to escape the curvature.

12. The method of claim 11, where the shapes of the plurality of curvatures are selected to be associated with an emission wavelength that photons are emitted from an active region.

13. The method of claim 7, where the surface of the LED is a p-type layer above an active region in the LED.

14. The method of claim 7, where the LED is an ultraviolet LED having wide band gap aluminum gallium nitride (AlGaN) quantum wells (QWs) with aluminum nitride (AlN) barriers. It can be applied for visible LEDs which has InGaN QWs with GaN as barriers as active region.

15. An apparatus, comprising:
a device having a first semiconductor material and a second semiconductor material separated by an active region; and
a plurality of curvatures formed on the second semiconductor material, where the curvatures formed from a monolayer of microspheres and the second semiconductor material.

16. The apparatus of claim 15, where the monolayer of microspheres is a monolayer of self-assembled microspheres.

17. The apparatus of claim 15, where the curvatures are formed from the second material.

18. The apparatus of claim 15, where the microspheres are dielectric.

19. The apparatus of claim 15, where the curvatures are formed as a result of reactive ion etching.

20. The apparatus of claim 15, where an index of refraction and an arc of the curvatures is selected to increase a light escape cone thereby reducing internal reflections.
